(19) United States
(12) Patent Application Publication
(10) Pub. No.: US 2015/0004431 A1
(43) Pub. Date: Jan. 1, 2015

(54) ANTI-CORROSION FILM, METAL SUBSTRATE WITH ANTI-CORROSION LAYER AND MANUFACTURING METHOD THEREOF

(71) Applicant: National Central University, Jhongli City (TW)

(72) Inventors: Chung-Jen TSENG, Zhongli City (TW); Shian-Ching JANG, Hsinchu County (TW); Tein-Chun CHENG, Taipei City (TW); Pei-Jung WU, Tainan City (TW); Hung-Cheng LIN, Zhongli City (TW); Pei Hua TSAI, Tainan City (TW)

(73) Assignee: National Central University, Jhongli City (TW)

(21) Appl. No.: 14/200,658

(22) Filed: Mar. 7, 2014

(30) Foreign Application Priority Data
Jun. 28, 2013 (TW) 102123190

(51) Int. Cl. C22C 45/10; C23C 14/16; C23C 14/10; B32B 15/01

(52) U.S. Cl. CPC C22C 45/10; B32B 15/01; C23C 14/165; C23C 14/10
USPC 428/613; 428/656; 204/192.15; 148/403

(57) ABSTRACT

The present invention relates to an anti-corrosion film, a metal substrate with an anti-corrosion layer and a manufacturing method thereof. The anti-corrosion film is at least one selected from the group consisting of: a Zr-based metallic glass film formed of Formula 1, a Zr—Cu-based metallic glass film formed of Formula 2, and a Ti-based metallic glass film formed of Formula 3, Formula 4 or Formula 5, wherein Formula 1 to Formula 5 are as described in the specification.

### CROSS REFERENCE TO RELATED APPLICATION

This application claims the benefits of the Taiwan Patent Application Serial Number 102123190, filed on Jun. 28, 2013, the subject matter of which is incorporated herein by reference.

### BACKGROUND OF THE INVENTION

1. Field of the Invention

The present invention relates to an anti-corrosion film, a metal substrate with an anti-corrosion layer and a manufacturing method thereof, and more particularly to an anti-corrosion film suitable for metal foam.

2. Description of Related Art

Corrosion of metallic materials not only causes damages to the material, endangers the safety of the equipment or devices, but also increases the cost for material replacement. Therefore, with the advance of technology, research on anti-corrosion has become more and more important and imperative in consideration of cost and equipment safety.

Anti-corrosion materials are widely used in many household appliances, including any metal articles that require anti-corrosion properties, such as aircrafts, vehicle parts, battery electrodes, and so on. The conventional methods for improving anti-corrosion of a metal article comprise coating, painting, and so on, by which a protective substance can be formed on the metal to provide protection from corrosive environments.

Currently, anti-corrosion treatments can be divided into metal coating, nonmetallic inorganic coating and organic paint coating. Although the organic paint coating provides desirable anti-corrosion effects, the raw material and solvent used are harmful to the environment, and thus its application is under increasing restriction.

In view of the increasing demand for anti-corrosion materials, the development of the anti-corrosion technology is becoming more and more important.

### SUMMARY OF THE INVENTION

An object of the present invention is to provide an anti-corrosion film which may be formed on various kinds of substrates so as to confer anti-corrosion properties to the substrate.

Another object of the present invention is to provide a metal substrate with an anti-corrosion layer, such that the easily corroded metal substrate can become corrosion-proof.

A further object of the present invention is to provide a method for manufacturing a metal substrate with an anti-corrosion layer, thereby conferring the anti-corrosion properties to the easily corroded metal substrate.

To achieve the above object, the present invention provides an anti-corrosion film, comprising at least one selected from the group consisting of a Zr-based metallic glass film formed of Formula 1, a Zr—Cu-based metallic glass film formed of Formula 2, and a Ti-based metallic glass film formed of Formula 3, Formula 4 or Formula 5, wherein the Formulas 1-5 are shown below:

(ZrₐCu_{b}Ni_{c}Al_{d})₁₀₀₋ₓSiₓ, [Formula 1]

wherein, 45≦a≦75, 25≦b≦35, 5≦c≦15, 5≦d≦15, and 0.1≦x≦10,

(ZrₑCu_{f}Al_{g}Agₕ)_{100-y}Si_{y}, [Formula 2]

wherein, 35≦e≦55, 35≦f≦55, 5≦g≦15, 5≦h≦15, and 0.1≦y≦10,

TiᵢCuⱼPdₖZrₗSiₘ, [Formula 3]

wherein, 40≦i≦75, 30≦j≦40, 10≦k≦20, 5≦l≦15, and 0.05≦m≦2,

TiₙTaₒSiₚZr_{q}, [Formula 4]

wherein, 30≦n≦80, 0≦o≦40, 1≦p≦20, and 5≦q≦40,

TiᵣCuₛZrₜPdᵤ, [Formula 5]

wherein, 40≦r≦75, 30≦s≦40, 5≦t≦15, 1 and 10≦u≦20.

Preferably, the anti-corrosion film is the Zr-based metallic glass film formed of Formula 1, the Zr—Cu-based metallic glass film formed of Formula 2, or the Ti-based metallic glass film formed of Formula 3, Formula 4 or Formula 5.

More preferably, the anti-corrosion film is a (Zr₅₃Cu₃₀Ni₉Al₈)_{99.5}Si_{0.5} metallic glass film or a (Zr₄₂Cu₄₂Al₈Ag₈)_{99.5}Si_{0.5} metallic glass film.

To achieve the another object, the present invention provides a metal substrate with an anti-corrosion layer, comprising; a metal substrate; and an anti-corrosion layer formed on the metal substrate, wherein the anti-corrosion layer comprises at least one selected from the group consisting of: a Zr-based metallic glass film formed of Formula 1, a Zr—Cu-based metallic glass film formed of Formula 2, and a Ti-based metallic glass film formed of Formula 3, Formula 4 or Formula 5, wherein the Formulas 1-5 are shown below:

(ZrₐCu_{b}Ni_{c}Al_{d})₁₀₀₋ₓSiₓ, [Formula 1]

wherein, 45≦a≦75, 25≦b≦35, 5≦c≦15, 5≦d≦15, and 0.1≦x≦10,

(ZrₑCu_{f}Al_{g}Agₕ)_{100-y}Si_{y}, [Formula 2]

wherein, 35≦e≦55, 35≦f≦55, 5≦g≦15, 5≦h≦15, and 0.1≦y≦10,

TiᵢCuⱼPdₖZrₗSiₘ, [Formula 3]

wherein, 40≦i≦75, 30≦j≦40, 10≦k≦20, 5≦l≦15, and 0.05≦m≦2,

TiₙTaₒSiₚZr_{q}, [Formula 4]

wherein, 30≦n≦80, 0≦o≦40, 1≦p≦20, and 5≦q≦40,

TiᵣCuₛZrₜPdᵤ, [Formula 5]

wherein, 40≦r≦75, 30≦s≦40, 5≦t≦15, and 10≦u≦20.

Preferably, the anti-corrosion layer is the Zr-based metallic glass film formed of Formula 1, the Zr—Cu-based metallic glass film formed of Formula 2, or the Ti-based metallic glass film formed of Formula 3, Formula 4 or Formula 5. More preferably, the anti-corrosion layer is a (Zr₅₃Cu₃₀Ni₉Al₈)_{99.5}Si_{0.5} metallic glass film or a (Zr₄₂Cu₄₂Al₈Ag8)99.5Si_{0.5} metallic glass film.

When the anti-corrosion layer is subjected to stress or thermal strain, since the thermal expansion coefficients and elastic modulus of the metal substrate and the anti-corrosion layer are different, discontinuous stress may be easily generated at the interface and result in peeling of the anti-corrosion layer, thereby losing its functions. In other words, during the heating or cooling process, the unequal thermal stresses (tensile stress or compressive stress) are generated between the anti-corrosion layer and the metal substrate due to the thermal expansion coefficient difference, and as a result, the adhesion of the anti-corrosion layer is reduced. To reduce the differences in the thermal expansion coefficient and the elastic modulus between the metal substrate and the anti-corrosion layer, it is preferable to interpose therebetween a buffer layer with a thermal expansion coefficient and elastic modulus ranging between those of the two materials. In the present invention, the buffer layer material is preferably at least one selected from the group consisting of: titanium, zirconium and chromium, more preferably pure titanium, pure zirconium or pure chromium, and most preferably pure titanium. The thickness of the buffer layer is preferably between 20-80 nm, more preferably between 40-60 nm, and can be adjusted if needed to improve the adhesion between the anti-corrosion layer and the metal substrate.

In the above-mentioned metal substrate with the anti-corrosion layer, the anti-corrosion layer may has a thickness ranging between 100-500 nm, and more preferably between 200-400 nm. In the present invention, the metal substrate is not particularly limited, and preferably a metal foam.

To achieve the further object, the present invention provides a method for manufacturing a metal substrate with an anti-corrosion layer, comprising the following steps in sequence: (A) providing an anti-corrosion target, wherein the anti-corrosion target comprises at least one selected from the group consisting of: a Zr-based metallic glass target represented by formula 1, a Zr—Cu-based metallic glass target represented by formula 2, and a Ti-based metallic glass target represented by Formula 3, Formula 4 or Formula 5; and (B) sputtering the anti-corrosion target on a metal substrate in a gas under a pressure of 1×10⁻⁴ to 1×10⁻² Pa, to form an anti-corrosion layer, wherein the Formulas 1-5 are shown below:

(ZrₐCu_{b}Ni_{c}Al_{d})₁₀₀₋ₓSiₓ, [Formula 1]

wherein, 45≦a≦75, 25≦b≦35, 5≦c≦15, 5≦d≦15, and 0.1≦x≦10,

(ZrₑCu_{f}Al_{g}Agₕ)_{100-y}S_{y}, [Formula 2]

wherein, 35≦e≦55, 35≦f≦55, 5≦g≦15, 5≦h≦15, and 0.1≦y≦10,

TiᵢCuⱼPdₖZrₗSiₘ, [Formula 3]

wherein, 40≦i≦75, 30≦j≦40, 10≦k≦20, 5≦l≦15, and 0.05≦m≦2,

TiₙTaₒSiₚZr_{q}, [Formula 4]

wherein, 30≦n≦80, 0≦o≦40, 1≦p≦20, and 5≦q≦40,

TiᵣCuₛZrₜPdᵤ, [Formula 5]

wherein, 40≦r≦75, 30≦s≦40, 5≦t≦15, and 10≦u≦20.

In the above-described manufacturing method, the anti-corrosion target is preferably the Zr-based metallic glass target represented by Formula 1, the Zr—Cu-based metallic glass target represented by Formula 2, or the Ti-based metallic glass target represented by Formula 3, Formula 4 or Formula 5. More preferably, the anti-corrosion target is a (Zr₅₃Cu₃₀Ni₉Al₈)_{99.5}Si_{0.5} metallic glass target or a (Zr₄₂Cu₄₂Al₈Ag₈)_{99.5}Si_{0.5} metallic glass target. The metal substrate is not particularly limited, and preferably a metal foam.

In the above-described manufacturing method, the gas is an inert gas or nitrogen, wherein the inert gas may be at least one selected from the group consisting of: helium, neon and argon.

In the above-described method, a step (A′) of forming a buffer layer on the metal substrate may be performed after the step (A).

The method for forming the buffer layer is not particularly limited. For example, the buffer layer coating may be prepared by DC magnetron sputtering in an argon atmosphere under a working pressure of 4×10⁻³ Torr. In addition, the material of the buffer layer is preferably at least one selected from the group consisting of: titanium, zirconium or chromium, and preferably titanium. The buffer layer may have a thickness between 20-80 nm, and preferably between 40-60 nm, and can be adjusted accordingly if needed.

In the metal substrate with anti-corrosion properties formed according to the above manufacturing method, the anti-corrosion layer may have a thickness ranging between 100-500 nm, and more preferably between 200-400 nm. Further, the metal substrate used in the above manufacturing method is not particularly limited, and preferably a metal foam.

### BRIEF DESCRIPTION OF THE DRAWINGS

FIG. 1 shows a schematic diagram of the corrosion test I according to the present invention.

FIG. 2 shows a schematic diagram of the corrosion test II according to the present invention.

FIG. 3 shows a schematic diagram of the corrosion test III according to the present invention.

### DETAILED DESCRIPTION OF THE PREFERRED EMBODIMENT

Hereinafter, exemplary embodiments of the present invention will be described in detail. However, the present invention is not limited to the embodiments disclosed below, but can be implemented in various forms. The following embodiments are described in order to enable those of ordinary skill in the art to embody and practice the present invention, and those skilled in the art will appreciate that various modifications, additions and substitutions are possible.

### Example

First, the Zr-based metallic glass represented by Formula 1, the Zr—Cu-based metallic glass represented by Formula 2, or the Ti-based metallic glass represented by Formula 3, Formula 4 or Formula 5 was used. More preferably, an anti-corrosion material such as a (Zr₅₃Cu₃₀Ni₉Al₈)_{99.5}Si_{0.5} metallic glass or a (Zr₄₂Cu₄₂Al₈Ag₈)_{99.5}Si_{0.5} metallic glass was used as a raw material, and melted to form an ingot, and then subjected to vacuum suction casting to form a Zr-based metallic glass plate, Zr—Cu-based metallic glass plate or a Ti-based metallic glass plate. Thereafter, the metallic glass plates were cut to show non-vertical cutting planes, and then the cutting planes were sequentially stacked and assembled to form a Zr-based, Zr—Cu-based, or Ti-based metallic glass target.

A metal foam as the substrate was subjected to surface treatments, including grinding, electrolytic polishing and so on in advance. Subsequently, in an inert gas under a pressure of 1×10⁻⁴ to 1×10⁻² Pa, the metal foam was subjected to sputtering coating to form a Zr-based metallic glass film, Zr—Cu-based metallic glass film or a Ti-based metallic glass film as an anti-corrosion layer on the surface of the metal foam. Here, the anti-corrosion layer had a thickness of 300 nm.

In order to enhance the adhesion between the anti-corrosion layer and the metal foam, a buffer layer was formed on the surface of the metal foam by DC magnetron sputtering in an argon atmosphere under a working pressure of 4×10⁻³ Torr to form a titanium buffer layer of 50 nm in thickness.

### Test Example

The metal foam prepared in the Example was tested for the anti-corrosion properties by a corrosion measurement system with bare stainless steel as a standard sample.

In this Test Example, corrosion resistance was determined by polarization measurements performed with an Autolab PGSTAT302N potentiostat using a three-electrode system, in which the reference electrode was Ag/AgCl, the working electrode was the test sample, and the auxiliary electrode was platinum. The scanning range was from −0.6 V to 1.2 V vs Ag/AgCl, while the scan rate was 1 mV/s.

The test sample was dipped in advance in a corrosive environment for 10 minutes to achieve a steady state before testing, and the anti-corrosion test was subsequently performed with the following conditions.

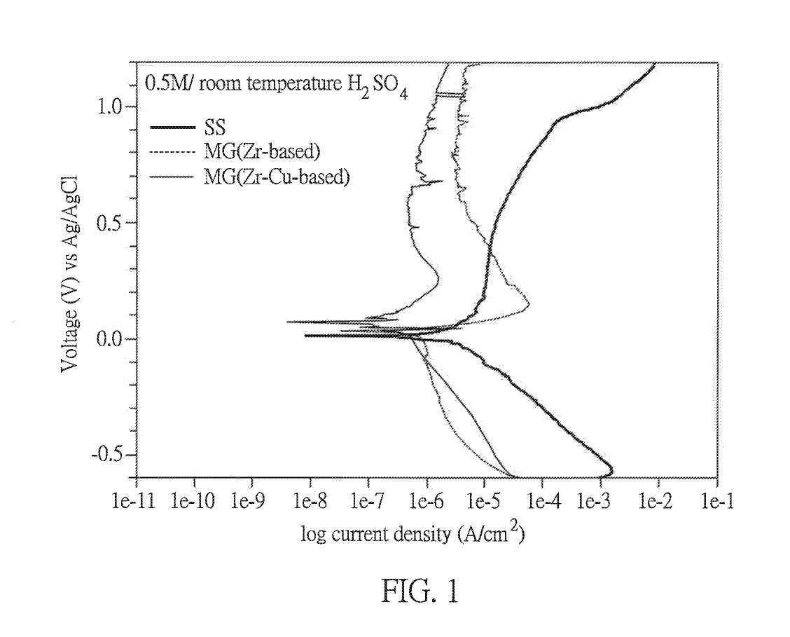

Corrosion Test I: Test samples including a bare stainless steel standard sample (SS), the metal foam having Zr-based metallic glass film, and the metal foam having Zr—Cu-based metallic glass film were tested under a corrosive environment of 0.5 M sulfuric acid at room temperature. The test results are shown in Table 1 and FIG. 1:

TABLE 1

| Sample | Ecorr (V) | Icorr (A/cm²) |
|---|---|---|
| SS | 0.0134 | 2.21 × 10⁻⁶ |
| MG I Zr-based | 0.0378 | 2.54 × 10⁻⁶ |
| MG II (Zr—Cu-based) | 0.0531 | 3.50 × 10⁻⁷ |

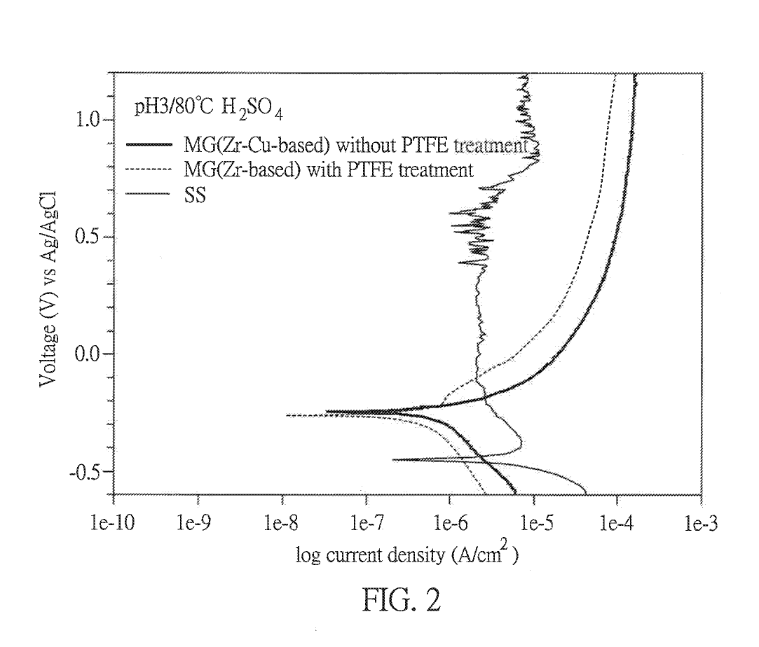

Corrosion Test II: Test samples including a bare stainless steel standard sample (SS), the metal foam having the Zr—Cu-based metallic glass film without 40 wt % of PTFE hydrophobic treatment, and the metal foam having the Zr—Cu-based metallic glass film with 40 wt % of PTFE hydrophobic treatment were tested under a corrosive environment of sulfuric acid of pH 3 at a temperature of 80° C. The test results are shown in Table 2 and FIG. 2:

TABLE 2

| Sample | Ecorr (V) | Icorr (A/cm²) |
|---|---|---|
| SS | −0.4504 | 4.00 × 10⁻⁶ |
| MG (Zr—Cu-based) without PTFE | −0.2429 | 3.995 × 10⁻⁷ |
| hydrophobic treatment | | |
| MG(Zr—Cu-based) with PTFE | −0.2582 | 2.88 × 10⁻⁷ |
| hydrohobic treatment | | |

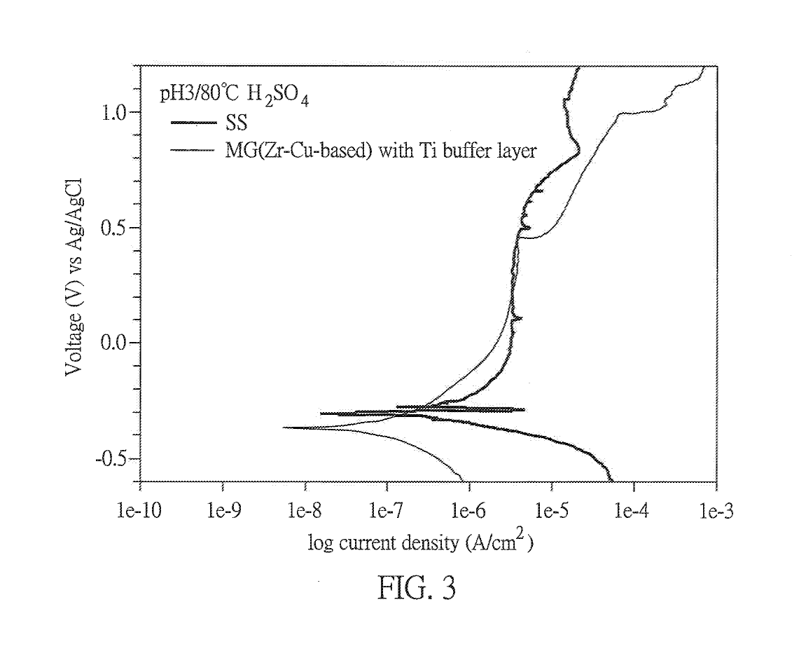

Corrosion Test III: Test samples including a bare stainless steel standard sample (SS), and the metal foam having Zr—Cu-based metallic glass film without a Ti buffer layer were tested under a corrosive environment of sulfuric acid of pH 3 at a temperature of 80° C. The test results are shown in Table 3 and FIG. 3:

TABLE 3

| Sample | Ecorr (V) | Icorr (A/cm²) |
|---|---|---|
| SS | −0.3040 | 2.32 × 10⁻⁷ |
| MG (Zr—Cu-based) without Ti | −0.3680 | 4.31 × 10⁻⁸ |
| buffer layer | | |

The corrosion potential (Ecorr) and corrosion current (Icorr) in the corrosion polarization graph indicate the corrosion resistance of the test samples. A greater corrosion potential and a smaller corrosion current represent a better corrosion resistance of the test sample. Thus, according to the results of Tables 1 to 3 and FIGS. 1 to 3, the metal foam having Zr-based metallic glass film, the metal foam having Zr—Cu-based metallic glass film, and the metal foam having Zr—Cu-based metallic glass film without a Ti buffer layer, prepared by the Example, exhibited a better anti-corrosion property, compared with the bare stainless steel standard sample (SS). Indeed, the Zr-based metallic glass film, the Zr—Cu-based metallic glass film, and the Ti-based metallic glass film of the present invention all possess anti-corrosion properties and are suitable for various substrates demanding for corrosion resistance, especially metal foams.

Although the present invention has been explained in relation to its preferred embodiment, it is to be understood that many other possible modifications and variations can be made without departing from the spirit and scope of the invention as hereinafter claimed.

What is claimed is:

1. An anti-corrosion film, comprising at least one selected from the group consisting of: a Zr-based metallic glass film formed of Formula 1, a Zr—Cu-based metallic glass film formed of Formula 2, and a Ti-based metallic glass film formed of Formula 3, Formula 4 or Formula 5,
(ZrₐCu_{b}Ni_{c}Al_{d})₁₀₀₋ₓSiₓ, [Formula 1]
wherein, 45≦a≦75, 25≦b≦35, 5≦c≦15, 5≦d≦15, and 0.1≦x≦10,
(ZrₑCu_{f}Al_{g}Agₕ)_{100-y}Si_{y}, [Formula 2]
wherein, 35≦e≦55, 35≦f≦55, 5≦g≦15, 5≦h≦15, and 0.1 ≦y≦10,
TiᵢCuⱼPdₖZrₗSiₘ, [Formula 3]
wherein, 40≦i≦75, 30≦j≦40, 10≦k≦20, 5≦l≦15, and 0.05≦m≦2,
TiₙTaₒSiₚZr_{q}, [Formula 4]
wherein, 30≦n≦80, 0≦o≦40, 1≦p≦20, and 5≦q≦40,
TiᵣCuₛZrₜPdᵤ, [Formula 5]
wherein, 40≦r≦75, 30≦s≦40, 5≦t≦15, and 10≦u≦20.

2. The anti-corrosion film of claim 1, wherein the anti-corrosion film is the Zr-based metallic glass film formed of Formula 1, the Zr—Cu-based metallic glass film formed of Formula 2, or the Ti-based metallic glass film formed of Formula 3, Formula 4 or Formula 5.

3. The anti-corrosion film of claim 1, wherein the anti-corrosion film is a (Zr₅₃Cu₃₀Ni₉Al₈)_{99.5}Si_{0.5} metallic glass film or a (Zr₄₂Cu₄₂Al₈Ag₈)_{99.5}Si_{0.5} metallic glass film.

4. A metal substrate with an anti-corrosion layer, comprising:
a metal substrate; and
an anti-corrosion layer formed on the metal substrate, wherein the anti-corrosion layer comprises at least one selected from the group consisting of: a Zr-based metallic glass film formed of Formula 1, a Zr—Cu-based metallic glass film formed of Formula 2, and a Ti-based metallic glass film formed of Formula 3, Formula 4 or Formula 5,
(ZrₐCu_{b}Ni_{c}Al_{d})₁₀₀₋ₓSiₓ, [Formula 1]
wherein, 45≦a≦75, 25≦b≦35, 5≦c≦15, 5≦d≦15, and 0.1≦x≦10,
(ZrₑCu_{f}Al_{g}Agₕ)_{100-y}Si_{y}, [Formula 2]
wherein, 35≦e≦55, 35≦f≦55, 5≦g≦15, 5≦h≦15, and 0.1≦y≦10,
TiᵢCuⱼPdₖZrₗSiₘ, [Formula 3]
wherein, 40≦i≦75, 30≦j≦40, 10≦k≦20, 5≦l≦15, and 0.05≦m≦2,
TiₙTaₒSiₚZr_{q}, [Formula 4]
wherein, 30≦n≦80, 0≦o≦40, 1≦p≦20, and 5≦q≦40,
TiᵣCuₛZrₜYdᵤ, [Formula 5]
wherein, 40≦r≦75, 30≦s≦40, 5≦t≦15, and 10≦u≦20.

5. The metal substrate of claim 4, wherein the anti-corrosion layer is the Zr-based metallic glass film formed of Formula 1, the Zr—Cu-based metallic glass film formed of Formula 2, or the Ti-based metallic glass film formed of Formula 3, Formula 4 or Formula 5.

6. The metal substrate of claim 4, wherein the anti-corrosion film is a (Zr₅₃Cu₃₀Ni₉Al₈)_{99.5}Si_{0.5} metallic glass film or a (Zr₄₂Cu₄₂Al₈Ag₈)_{99.5}Si_{0.5} metallic glass film.

7. The metal substrate of claim 4, further comprising a buffer layer formed between the metal substrate and the anti-corrosion layer.

8. The metal substrate of claim 4, wherein the anti-corrosion layer has a thickness of 100-500 nm.

9. The metal substrate of claim 7, wherein the buffer layer is formed of at least one selected from the group consisting of titanium, zirconium and chromium.

10. The metal substrate of claim 9, wherein the buffer layer has a thickness of 20-80 nm.

11. The metal substrate of claim 4, wherein the metal substrate is a metal foam.

12. A method for manufacturing a metal substrate with an anti-corrosion layer, comprising the following steps in sequence:
(A) providing an anti-corrosion target, wherein the anti-corrosion target comprises at least one selected from the group consisting of: a Zr-based metallic glass target represented by Formula 1, a Zr—Cu-based metallic glass target represented by Formula 2, and a Ti-based metallic glass target represented by Formula 3, Formula 4 or Formula 5; and
(B) sputtering the anti-corrosion target on a metal substrate in a gas under a pressure of 1×10⁻⁴ to 1×10⁻² Pa, to form an anti-corrosion layer,
(ZrₐCu_{b}Ni_{c}Al_{d})₁₀₀₋ₓSiₓ, [Formula 1]
wherein, 45≦a≦75, 25≦b≦35, 5≦c≦15, 5≦d≦15, and 0.1≦x≦10,
(ZrₑCu_{f}Al_{g}Agₕ)_{100-y}Si_{y}, [Formula 2]
wherein, 35≦e≦55, 35≦f≦55, 5≦g≦15, 5≦h≦15, and 0.1≦y≦10,
TiᵢCuⱼPdₖZrₗSiₘ, [Formula 3]
wherein, 40≦i≦75, 30≦j≦40, 10≦k≦20, 5≦l≦15, and 0.05≦m≦2,
TiₙTaₒSiₚZr_{q}, [Formula 4]
wherein, 30≦n≦80, 0≦o≦40, 1≦p≦20, and 5≦q≦40,
TiᵣCuₛZrₜPdᵤ, [Formula 5]
wherein, 40≦r≦75, 30≦s≦40, 5≦t≦15, and 10≦u≦20.

13. The method of claim 12, wherein the anti-corrosion target is the Zr-based metallic glass target represented by Formula 1, the Zr—Cu-based metallic glass target represented by Formula 2, or the Ti-based metallic glass target represented by Formula 3, Formula 4 or Formula 5.

14. The method of claim 12, wherein the anti-corrosion target is a (Zr₅₃Cu₃₀Ni₉Al₈)_{99.5}Si_{0.5} metallic glass target or a (Zr₄₂Cu₄₂Al₈Ag₈)_{99.5}Si_{0.5} metallic glass target.

15. The method of claim 12, wherein the metal substrate is a metal foam.

16. The method of claim 12, wherein, in the step (B), the gas is an inert gas or nitrogen.

17. The method of claim 12, further comprising a step (A′) after the step (A),
(A′) forming a buffer layer on the metal substrate.

18. The method of claim 12, wherein the anti-corrosion layer has a thickness of 100-500 nm.

19. The method of claim 17, wherein the buffer layer is formed of at least one material selected from the group consisting of titanium, zirconium and chromium.

20. The method of claim 17, wherein the buffer layer has a thickness of 20-80 nm.
